(19) United States
(12) Patent Application Publication
(10) Pub. No.: US 2017/0236856 A1
(43) Pub. Date: Aug. 17, 2017

(54) IMAGING PANEL, METHOD OF PRODUCING IMAGING PANEL, AND X-RAY IMAGING DEVICE

(71) Applicant: Sharp Kabushiki Kaisha, Sakai City, Osaka (JP)

(72) Inventors: Kazuhide TOMIYASU, Sakai City (JP); Tadayoshi MIYAMOTO, Sakai City (JP)

(21) Appl. No.: 15/501,506

(22) PCT Filed: Jul. 30, 2015
(86) PCT No.: PCT/JP2015/071574

§ 371 Date: Feb. 3, 2017

(30) Foreign Application Priority Data
Aug. 5, 2014 (JP) 2014-159793

(51) Int. Cl. H01L 27/146; H04N 5/32; G01T 1/20

(52) U.S. Cl. CPC H01L 27/14603; G01T 1/2018; H01L 27/14663; H01L 27/14616; H01L 27/14636; H01L 27/14689; H04N 5/32; H01L 29/78693

(57) ABSTRACT

It is an object of the invention to secure a large area of a photodiode and suppress operation property variation and malfunction in an imaging panel and an X-ray imaging device. An imaging panel (10) includes a substrate (40), a TFT (14), an interlayer insulating film (44), a metal layer (45), and a photodiode (15). A data line (12) and the photodiode (15) face each other in a thickness direction of the substrate. The interlayer insulating film (44), which is disposed between the TFT (14) and the photodiode (15), is an SOG film or a photosensitive resin film.

### TECHNICAL FIELD

The present invention relates to an imaging panel, a method of producing the imaging panel, and an X-ray imaging device.

### BACKGROUND ART

A known X-ray imaging device includes an imaging panel provided with a plurality of pixel parts and configured to capture an X-ray image. Such an X-ray imaging device includes a photodiode configured to convert emitted X-rays to electric charges. In an indirect X-ray imaging device, a scintillator converts emitted X-rays to scintillation light and a photodiode converts the scintillation light thus converted to electric charges. The converted electric charges are read by a thin film transistor (hereinafter, also referred to as a “TFT”) in operation which is included in a pixel part. An X-ray image is obtained by reading the electric charges.

Patent Literature 1 discloses a photosensor including a glass substrate, a base insulating film, a switching element, and a photodiode. The base insulating film in the photosensor is provided on the glass substrate and has a lower dielectric constant than that of the glass substrate. The switching element includes a drain electrode having an extended portion in direct contact with a surface of the base insulating film. The photodiode is provided on the extended portion of the drain electrode. According to Patent Literature 1, the photodiode achieves reduction in coupling capacitance between the photodiode and a data line.

### CITATION LIST

### Patent Literature

Patent Literature 1: JP 2009-59975 A

### SUMMARY OF THE INVENTION

Research and development have been made to increase an area of a photodiode in order for increase in area of receiving X-rays or scintillation light.

Applicable examples of the method of increasing the area of the photodiode include disposing the photodiode so as to be overlapped with a data line. Disposing the photodiode and the data line overlapped with each other will cause formation of coupling capacitance between the data line and the photodiode and generation of signal noise at the data line. This may cause operation property variation or malfunction of an X-ray imaging panel.

It is difficult to thicken an existing insulating film for reduction in coupling capacitance between a data line and a photodiode. The existing insulating film thickened in accordance with the CVD method or the like will need longer film formation time, thus leading to deteriorated processing capacity in the production process and deteriorated yield.

It is an object of the present invention to secure a large area of a photodiode and suppress operation property variation and malfunction in an imaging panel and an X-ray imaging device.

In order to achieve the object mentioned above, an imaging panel according to an embodiment of the present invention is configured to generate an image in accordance with X-rays having been transmitted through a target, and the imaging panel includes: a substrate; a plurality of thin film transistors provided on the substrate; a data line configured to supply the plurality of thin film transistors with a data signal; an interlayer insulating film provided on the substrate and covering the thin film transistors and the data line; a plurality of contact holes penetrating the interlayer insulating film and reaching the thin film transistors, respectively; a plurality of metal layers each covering an inner side surface of a corresponding one of the contact holes and the interlayer insulating film and connected to a corresponding one of the thin film transistors; and a plurality of photodiodes each provided on and in contact with a corresponding one of the metal layers. Part of the data line and part of the photodiode are disposed opposite to each other in a thickness direction of the substrate. The interlayer insulating film is a spin on glass (SOG) film or a photosensitive resin film.

In order to achieve the object mentioned above, a method of producing an imaging panel according to an embodiment of the present invention relates to a method of producing an imaging panel configured to generate an image in accordance with X-rays having been transmitted through a target, and the method includes: forming a plurality of thin film transistors and a data line on a substrate; forming, on the substrate, an interlayer insulating film covering the thin film transistors and the data line in accordance with a spin coating method or a slit coating method; forming, in the interlayer insulating film, a plurality of contact holes each reaching a corresponding one of the thin film transistors; forming a metal film covering the interlayer insulating film and an inner side surface of each of the contact holes; and forming a plurality of photodiodes respectively corresponding to the contact holes by forming a semiconductor film and then patterning the semiconductor film into island shapes by dry etching.

The present invention provides an imaging panel and an X-ray imaging device securing a large area of a photodiode and inhibiting formation of coupling capacitance between a data line and the photodiode to suppress operation property variation and malfunction.

### BRIEF DESCRIPTION OF DRAWINGS

FIG. 1 is a pattern diagram of an X-ray imaging device according to an embodiment.

FIG. 2 is a pattern diagram depicting a schematic configuration of an imaging panel of FIG. 1.

FIG. 3 is a plan view of a pixel in the imaging panel of FIG. 2.

FIG. 4A is a sectional view taken along line A-A, of the pixel of FIG. 3.

FIG. 4B is a sectional view taken along line B-B, of the pixel of FIG. 3.

FIG. 5 includes a sectional view taken along line A-A and a sectional view taken along line B-B of the pixel of FIG. 3 in a process of producing a gate electrode of the pixel.

FIG. 6 includes a sectional view taken along line A-A and a sectional view taken along line B-B in a process of producing a gate insulating film of the pixel of FIG. 3.

FIG. 7 includes a sectional view taken along line A-A and a sectional view taken along line B-B in a process of producing a semiconductor active layer, a source electrode, and a drain electrode of the pixel of FIG. 3.

FIG. 8 includes a sectional view taken along line A-A and a sectional view taken along line B-B in a process of producing a passivation film of the pixel of FIG. 3.

FIG. 9 includes a sectional view taken along line A-A and a sectional view taken along line B-B in a process of producing an interlayer insulating film of the pixel of FIG. 3.

FIG. 10 includes a sectional view taken along line A-A and a sectional view taken along line B-B in a process of producing a first contact hole of the pixel of FIG. 3.

FIG. 11 includes a sectional view taken along line A-A and a sectional view taken along line B-B in a process of producing a metal film and a photodiode of the pixel of FIG. 3.

FIG. 12 includes a sectional view taken along line A-A and a sectional view taken along line B-B in a process of producing the photodiode of the pixel of FIG. 3.

FIG. 13 includes a sectional view taken along line A-A and a sectional view taken along line B-B in a process of producing an electrode and a metal layer of the pixel of FIG. 3.

FIG. 14 includes a sectional view taken along line A-A and a sectional view taken along line B-B in a process of producing a second interlayer insulating film of the pixel of FIG. 3.

FIG. 15 includes a sectional view taken along line A-A and a sectional view taken along line B-B in a process of producing a photosensitive resin layer of the pixel of FIG. 3.

FIG. 16 includes a sectional view taken along line A-A and a sectional view taken along line B-B in a process of producing the photosensitive resin layer and a bias wire of the pixel of FIG. 3.

FIG. 17 is a sectional view of a pixel in an imaging panel including a top gate TFT according to a modification example.

FIG. 18 is a sectional view of a pixel in an imaging panel including a TFT provided with an etch stopper layer according to another modification example.

### DESCRIPTION OF EMBODIMENTS

An imaging panel according to an embodiment of the present invention is configured to generate an image in accordance with X-rays having been transmitted through a target, and the imaging panel includes: a substrate; a plurality of thin film transistors provided on the substrate; a data line configured to supply the plurality of thin film transistors with a data signal; an interlayer insulating film provided on the substrate and covering the thin film transistors and the data line; a plurality of contact holes penetrating the interlayer insulating film and reaching the thin film transistors, respectively; a plurality of metal layers each covering an inner side surface of a corresponding one of the contact holes and the interlayer insulating film and connected to a corresponding one of the thin film transistors; and a plurality of photodiodes each provided on and in contact with a corresponding one of the metal layers. Part of the data line and part of the photodiode are disposed opposite to each other in a thickness direction of the substrate. The interlayer insulating film is an SOG film or a photosensitive resin film (a first configuration).

In the imaging panel having the first configuration, part of the data line and part of the photodiode are disposed opposite to each other in the thickness direction to secure a large area of the photodiode and achieve excellent conversion efficiency.

The imaging panel having the first configuration also includes the interlayer insulating film of the SOG film or the photosensitive resin film provided on the thin film transistor and the data line, to secure an adequate distance between the data line and the photodiode facing each other in the thickness direction. This configuration thus reduces coupling capacitance formed between the data line and the photodiode and inhibits generation of signal noise at the data line to suppress malfunction and operation property variation of the imaging panel.

The imaging panel having the first configuration further includes the metal layer below each of the photodiodes, to enable forming and patterning the photodiode in the state where a metal film is provided entirely on a surface of the substrate. In other words, the metal film covers the surface of the interlayer insulating film when the photodiode is patterned. The metal film thus protects the interlayer insulating film of the SOG film or the photosensitive resin film when the photodiode is patterned, to prevent the SOG film or the photosensitive resin film from being etched together.

According to a second configuration, the thickness of the interlayer insulating film in the first configuration is in a range of 1 μm to 5 μm.

According to a third configuration, the imaging panel having the first or second configuration further includes a first insulating film covering the thin film transistor and the data line and provided below the interlayer insulating film. The interlayer insulating film has a dielectric constant less than that of the first insulating film.

According to a fourth configuration, the interlayer insulating film in any one of the first to third configurations has a relative dielectric constant in a range of 2.5 to 4.

An X-ray imaging device according to the present invention includes: the imaging panel having any one of the first to fourth configurations; a controller configured to control gate voltage of each of the thin film transistors and read a data signal according to electric charges converted by the photodiodes via the data line; and an X-ray source configured to emit X-rays (a fifth configuration).

A method of producing an imaging panel according to an embodiment of the present invention relates to a method of producing an imaging panel configured to generate an image in accordance with X-rays having been transmitted through a target, and the method includes: forming a plurality of thin film transistors and a data line on a substrate; forming, on the substrate, an interlayer insulating film covering the thin film transistors and the data line in accordance with a spin coating method or a slit coating method; forming, in the interlayer insulating film, a plurality of contact holes each reaching a corresponding one of the thin film transistors; forming a metal film covering the interlayer insulating film and an inner side surface of each of the contact holes; and forming a plurality of photodiodes respectively corresponding to the contact holes by forming a semiconductor film and then patterning the semiconductor film into island shapes by dry etching (a first production method).

The first production method includes forming the interlayer insulating film in accordance with the spin coating method or the slit coating method, to achieve formation of the insulating film securing an adequate distance in the thickness direction between the data line and the photodiode. The obtained imaging panel accordingly reduces coupling capacitance formed between the data line and the photodiode. The imaging panel produced in accordance with this production method reduces coupling capacitance formed between the data line and the photodiode to inhibit generation of signal noise at the data line and thus suppress malfunction and operation property variation of the imaging panel.

A second production method is achieved by adding, to the first production method, obtaining a metal layer, after forming the plurality of photodiodes, by wet etching to remove a region not covered with the photodiodes in the metal film.

Embodiments of the present invention will be described in detail below with reference to the drawings. Identical or corresponding portions in the drawings will be denoted by identical reference signs and will not be described repeatedly.

The expression “connected” in the present description indicates connection between two members in contact with each other as well as electrical connection between two members via a third conductive member disposed between the two members.

### Embodiment 1

### (Configuration)

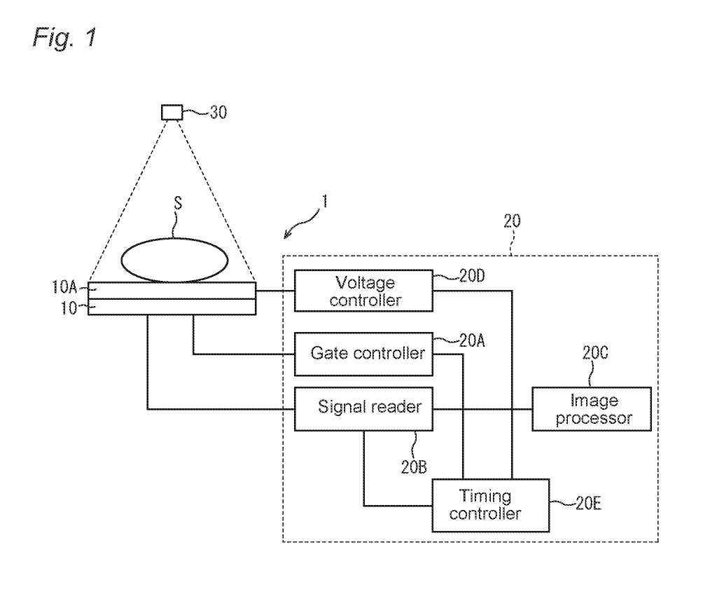

FIG. 1 is a pattern diagram of an X-ray imaging device 1 according to the embodiment 1. The X-ray imaging device 1 includes an imaging panel 10 and a controller 20. X-rays are applied from an X-ray source 30 to a target S, and the X-rays having been transmitted through the target S are converted to fluorescence (hereinafter, referred to as scintillation light) by a scintillator 10A disposed on the imaging panel 10. The X-ray imaging device 1 captures the scintillation light with use of the imaging panel 10 and the controller 20 to obtain an X-ray image.

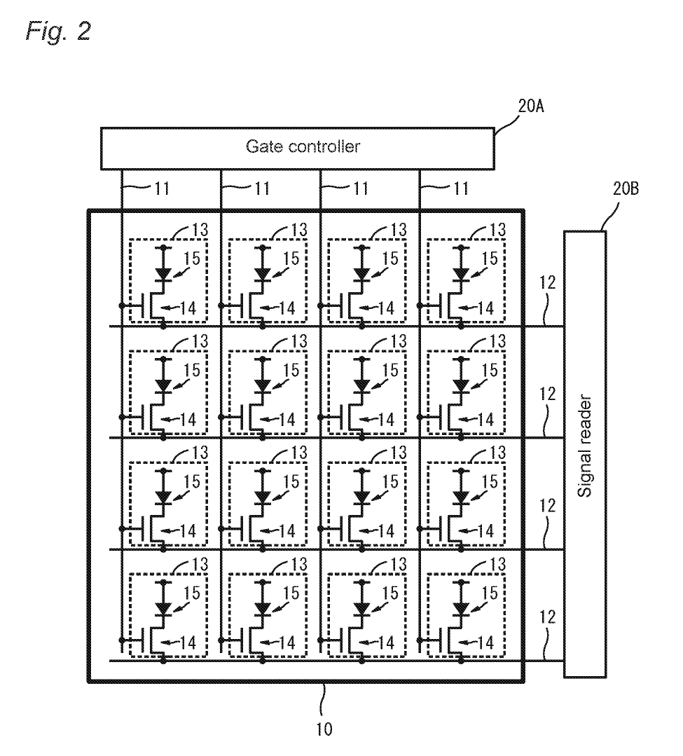

FIG. 2 is a pattern diagram depicting a schematic configuration of the imaging panel 10. As depicted in FIG. 2, the imaging panel 10 includes a plurality of gate lines 11 and a plurality of data lines 12 crossing the gate lines 11. The imaging panel 10 further includes a plurality of pixels 13 defined by the gate lines 11 and the data lines 12. FIG. 2 exemplifies the imaging panel 10 including 16 pixels 13 (in four lines and four columns), although the imaging panel 10 is not limited in the number of pixels.

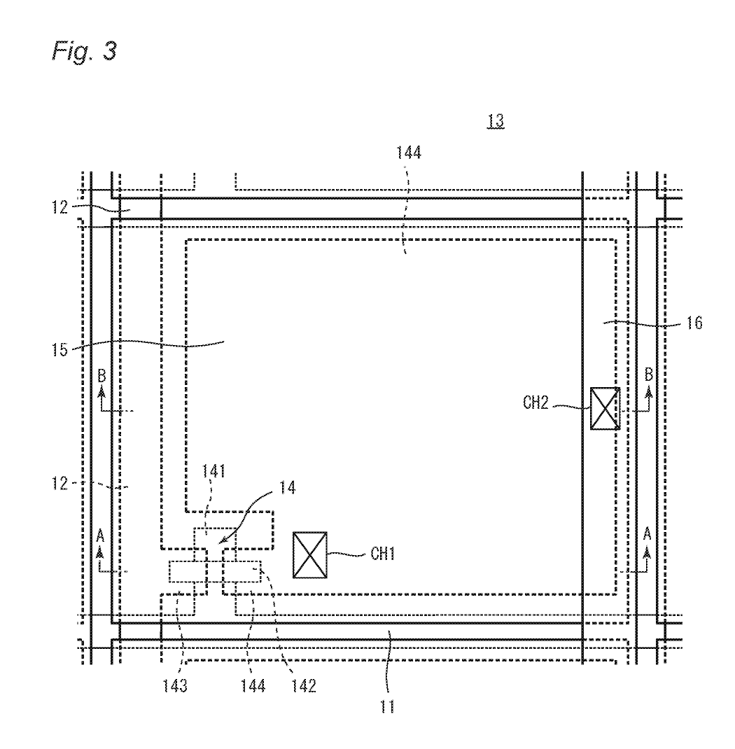

The pixels 13 each include a TFT 14 connected to a corresponding one of the gate lines 11 and a corresponding one of the data lines 12, and a photodiode 15 connected to the TFT 14. Although not depicted in FIG. 2, each of the pixels 13 is further provided with a bias wire 16 (see FIG. 3) configured to supply the photodiode 15 with bias voltage and disposed substantially in parallel with the data line 12.

In each of the pixels 13, the photodiode 15 converts the scintillation light converted from the X-rays having been transmitted through the target S to electric charges according to the amount of the scintillation light.

The gate lines 11 in the imaging panel 10 are sequentially switched to a selected state by a gate controller 20A, and the TFT 14 connected to the gate line 11 in the selected state is switched into an ON state. When the TFT 14 comes into the ON state, a data signal according to the electric charges converted by the photodiode 15 is transmitted to the data line 12.

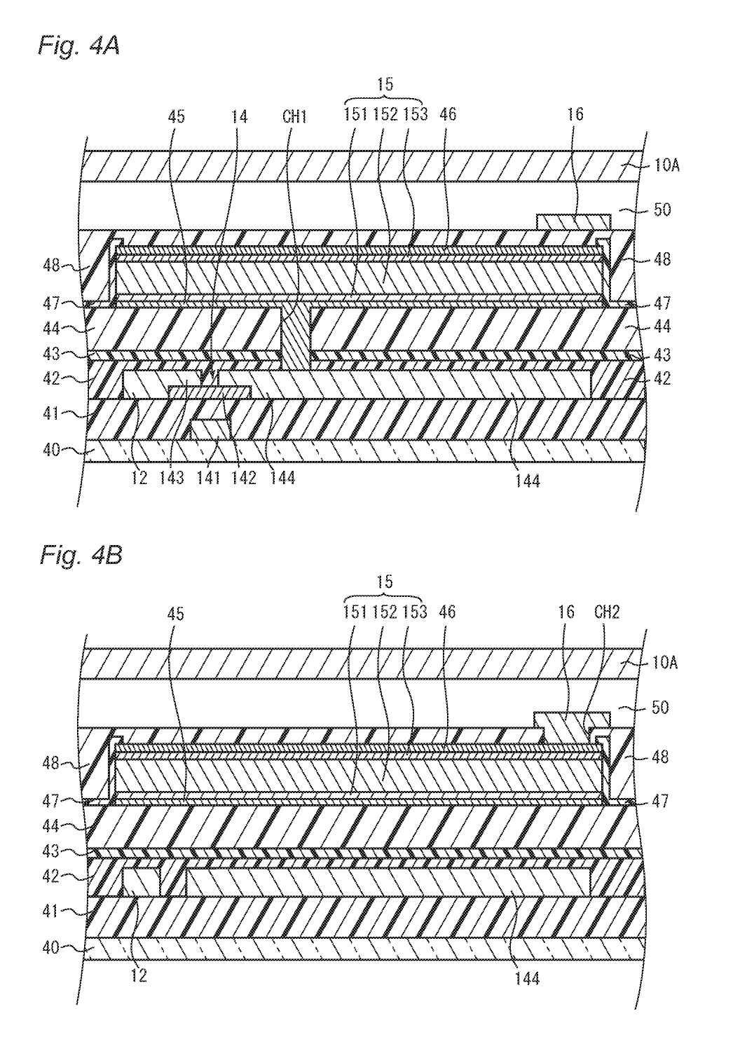

Described next is a specific configuration of the pixel 13. FIG. 3 is a plan view of the pixel 13 in the imaging panel 10 depicted in FIG. 2. FIG. 4A is a sectional view taken along line A-A, of the pixel 13 of FIG. 3, and FIG. 4B is a sectional view taken along line B-B, of the pixel 13 of FIG. 3.

As depicted in FIGS. 4A and 4B, the pixel 13 is provided on a substrate 40. The substrate 13 is an insulating substrate, examples of which include a glass substrate, a silicon substrate, a heat-resistant plastic substrate, and a resin substrate. Specifically, the plastic substrate or the resin substrate can be made of polyethylene terephthalate (PET), polyethylene naphthalate (PEN), polyether sulfone (PES), acryl, polyimide, or the like.

As depicted in FIGS. 4A and 4B, the TFT 14 includes a gate electrode 141, a semiconductor active layer 142 disposed above the gate electrode 141 with a gate insulating film 41 being interposed therebetween, and a source electrode 143 and a drain electrode 144 connected to the semiconductor active layer 142.

The gate electrode 141 is provided in contact with a first surface in the thickness direction (hereinafter, referred to as a main surface) of the substrate 40. The gate electrode 141 is made of a metal such as aluminum (Al), tungsten (W), molybdenum (Mo), tantalum (Ta), chromium (Cr), titanium (Ti), or copper (Cu), an alloy thereof, or a metal nitride thereof. The gate electrode 141 can alternatively include a plurality of stacked metal films. The gate electrode 141 according to the present embodiment has a stacked layer structure including a metal film made of aluminum and a metal film made of titanium stacked in the mentioned order.

As depicted in FIGS. 4A and 4B, the gate insulating film 41 is provided on the substrate 40 and covers the gate electrode 141. The gate insulating film 41 can be made of a silicon oxide (SiOₓ), a silicon nitride (SiNₓ), a silicon oxidized nitride (SiOₓN_{y}) (x>y), a silicon nitrided oxide (SiNₓO_{y}) (x>y), or the like.

As depicted in FIG. 4A, the semiconductor active layer 142 is provided in contact with the gate insulating film 41. The semiconductor active layer 142 is made of an oxide semiconductor. Examples of the oxide semiconductor include an amorphous oxide semiconductor containing InGaO₃(ZnO)₅, a magnesium zinc oxide (MgₓZn₁₋ₓO), a cadmium zinc oxide (CdₓZn₁₋ₓO), cadmium oxide (CdO), or indium (In), gallium (Ga), and zinc (Zn) at predetermined ratios. The semiconductor active layer 142 can be made of ZnO containing, as an additive, one or a plurality of impurity elements in Groups 1, 13, 14, 15, and 17, in a noncrystalline (amorphous) state or in a polycrystalline state. The ZnO can be in a microcrystalline state mixedly including the amorphous state and the polycrystalline state, or contains no additive of any impurity element.

As depicted in FIG. 4A, the source electrode 143 and the drain electrode 144 are provided in contact with the semiconductor active layer 142 and the gate insulating film 41. As depicted in FIG. 3, the source electrode 143 is connected to the data line 12. As depicted in FIG. 4A, the drain electrode 144 is connected to a metal layer 45 to be described later via a first contact hole CH1. The source electrode 143, the data line 12, and the drain electrode 144 are provided in an identical layer.

The source electrode 143, the data line 12, and the drain electrode 144 are made of a metal such as aluminum (Al), tungsten (W), molybdenum (Mo), tantalum (Ta), chromium (Cr), titanium (Ti), or copper (Cu), an alloy thereof, or a metal nitride thereof. The source electrode 143, the data line 12, and the drain electrode 144 can alternatively be made of a light-transmissive material such as indium tin oxide (ITO), indium zinc oxide (IZO), indium tin oxide containing silicon oxide (ITSO), indium oxide (In₂O₃), tin oxide (SnO₂), zinc oxide (ZnO), or titanium nitride, or appropriate combinations thereof.

The source electrode 143, the data line 12, and the drain electrode 144 can alternatively include a plurality of stacked metal films. The source electrode 143, the data line 12, and the drain electrode 144 according to the present embodiment have a stacked layer structure including a metal film made of titanium, a metal film made of aluminum, and a metal film made of titanium stacked in the mentioned order.

The data line 12 and the source electrode 143 are not necessarily provided in an identical layer. The data line 12 can alternatively be provided in a different layer. In this case, the data line 12 and the source electrode 143 are connected with each other via a contact hole or the like.

As depicted in FIGS. 4A and 4B, there is provided a first passivation film 42 covering the semiconductor active layer 142, the source electrode 143, the data line 12, and the drain electrode 144. The first passivation film 42 is made of silicon oxide (SiO₂) or the like. The first passivation film 42 is typically 10 to 400 nm thick.

As depicted in FIGS. 4A and 4B, there is provided a second passivation film 43 covering the first passivation film 42. The second passivation film 43 is made of silicon nitride (SiN) or the like. The second passivation film 43 is typically 10 to 400 nm thick.

The present invention does not necessarily need provision of such two passivation films covering the TFT 14 as in the present embodiment. For example, a passivation film having a single layer structure and made of silicon oxide (SiO₂) or silicon nitride (SiN) can alternatively be provided to cover the semiconductor active layer 142, the source electrode 143, the data line 12, and the drain electrode 144.

As depicted in FIGS. 4A and 4B, there is provided an interlayer insulating film 44 in contact with the passivation film 42. The interlayer insulating film 44 is an SOG film. Specifically, the interlayer insulating film 44 is an SiO₂ film formed in accordance with the slit coating method. The interlayer insulating film 44 can alternatively be an SiO₂ film formed in accordance with the spin coating method or the like instead of the slit coating method.

The interlayer insulating film 44 is typically 1 to 5 μm thick. Assuming that the interlayer insulating film 44 has a thickness d and a dielectric constant ∈, two conductors facing each other with the interlayer insulating film 44 being interposed therebetween (the data line 12 and the photodiode 15 herein) have an area S and form coupling capacitance C, the relational expression C=∈·(dS)⁻¹ is established.

The dielectric constant of the interlayer insulating film 44 is preferably less than the dielectric constants of the first passivation film 42 and the second passivation film 43. This decreases coupling capacitance to be formed via the interlayer insulating film 44. Preferred examples of the interlayer insulating film 44 include an organic SOG film having a low dielectric constant (low-k film). The interlayer insulating film 44 has a relative dielectric constant preferred to range from 2.5 to 4.

As depicted in FIG. 4A, the first passivation film 42, the second passivation film 43, and the interlayer insulating film 44 are provided with the first contact hole CH1 reaching the drain electrode 144.

As depicted in FIGS. 4A and 4B, the interlayer insulating film 44 is provided thereon with the metal layer 45. As depicted in FIG. 4A, the metal layer 45 also covers the inner wall surface of the first contact hole CH1. The metal layer 45 covers the inner wall surface of the first contact hole CH1 and is thus in contact with the drain electrode 144. The metal layer 45 is provided in a region substantially identical to a region provided with the photodiode 15 to be described later. That is, a plurality of metal layers 45 is provided correspondingly to the pixels 13, respectively.

The metal layer 45 is provided as a molybdenum (Mo) film, a titanium (Ti) film, a film made of an alloy thereof, or the like. The metal layer 45 can have a single layer structure or a stacked layer structure. The metal layer 45 according to the present embodiment is provided as a molybdenum (Mo) film.

As depicted in FIGS. 4A and 4B, the photodiode 15 is provided in contact with the metal layer 45. The photodiode 15 at least includes a first semiconductor layer of a first conductivity type and a second semiconductor layer of a second conductivity type in contrast to the first conductivity type. The photodiode 15 according to the present embodiment includes an n-type amorphous silicon layer 151 (the first semiconductor layer), an intrinsic amorphous silicon layer 152, and a p-type amorphous silicon layer 153 (the second semiconductor layer). The photodiode 15 is provided to be laid out substantially identically to the metal layer 45.

The n-type amorphous silicon layer 151 is made of amorphous silicon doped with an n-type impurity (e.g. phosphorus). The n-type amorphous silicon layer 151 is provided in contact with the drain electrode 144. The n-type amorphous silicon layer 151 is typically 20 to 100 nm thick. The n-type amorphous silicon layer 151 is connected with the drain electrode 144 via the metal layer 45.

The intrinsic amorphous silicon layer 152 is made of intrinsic amorphous silicon. The intrinsic amorphous silicon layer 152 is provided in contact with the n-type amorphous silicon layer 151. The intrinsic amorphous silicon layer is typically 200 to 2000 nm thick.

The p-type amorphous silicon layer 153 is made of amorphous silicon doped with a p-type impurity (e.g. boron). The p-type amorphous silicon layer 153 is provided in contact with the intrinsic amorphous silicon layer 152. The p-type amorphous silicon layer 153 is typically 10 to 50 nm thick.

The drain electrode 144 functions as a drain electrode of the TFT 14 and functions also as a lower electrode of the photodiode 15. The drain electrode 144 further functions as a reflective film reflecting scintillation light having been transmitted through the photodiode 15 to be directed to the photodiode 15.

As depicted in FIGS. 4A and 4B, the photodiode 15 is provided thereon with an upper electrode 46 functioning as an upper electrode of the photodiode 15. The upper electrode 46 is made of indium zinc oxide (IZO) or the like. The upper electrode 46 is provided to be laid out substantially identically to the metal layer 45 and the photodiode 15.

The drain electrode 144 functioning as a lower electrode, the metal layer 45 equal in potential to the drain electrode 144, the photodiode 15, and the upper electrode 46 configure a photoelectric transducer.

There is provided a third passivation film 47 in contact with the second passivation film 43. The third passivation film 47 covers side surfaces of the metal layer 45, the photodiode 15, and the upper electrode 46, and a peripheral edge of a light incident surface of the upper electrode 46. The third passivation film 47 can have a single layer structure including silicon oxide (SiO₂) or silicon nitride (SiN), or a stacked layer structure including silicon nitride (SiN) and silicon oxide (SiO₂) stacked in the mentioned order.

The third passivation film 47 is provided thereon with a photosensitive resin layer 48. The photosensitive resin layer 48 is made of an organic resin material or an inorganic resin material.

As depicted in FIG. 4B, the photosensitive resin layer 48 is provided with a second contact hole CH2 reaching the upper electrode 46.

As depicted in FIGS. 3, 4A, and 4B, the bias wire 16 is provided on the photosensitive resin layer 48 and substantially in parallel with the data line 12. The bias wire 16 is connected to a voltage controller 20D (see FIG. 1). As depicted in FIG. 4B, the bias wire 16 is connected to the upper electrode 46 via the second contact hole CH2 and applies bias voltage received from the voltage controller 20D to the upper electrode 46. The bias wire 16 has a stacked layer structure including indium zinc oxide (IZO) and molybdenum (Mo), for example.

As depicted in FIGS. 4A and 4B, the imaging panel 10, specifically, the photosensitive resin layer 48, is provided thereon with a protective layer 50 covering the bias wire 16, and the scintillator 10A is provided on the protective layer 50.

Described with reference to FIG. 1 again is a configuration of the controller 20. The controller 20 includes the gate controller 20A, a signal reader 20B, an image processor 20C, the voltage controller 20D, and a timing controller 20E.

As depicted in FIG. 2, the gate controller 20A is connected with the plurality of gate lines 11. The gate controller 20A applies, via each of the gate lines 11, predetermined gate voltage to the TFT 14 included in the pixel 13 connected to the gate line 11.

As depicted in FIG. 2, the signal reader 20B is connected with the plurality of data lines 12. The signal reader 20B reads, via each of the data lines 12, a data signal according to electric charges converted by the photodiode 15 included in the pixel 13. The signal reader 20B generates an image signal according to the data signal and transmits the image signal to the image processor 20C.

The image processor 20C generates an X-ray image in accordance with the image signal transmitted from the signal reader 20B.

The voltage controller 20D is connected to each of the bias wires 16. The voltage controller 20D applies predetermined bias voltage to the bias wire 16. The bias voltage is thus applied to the photodiode 15 via the upper electrode 46 connected to the bias wire 16.

The timing controller 20E controls operation timing of the gate controller 20A, the signal reader 20B, and the voltage controller 20D.

The gate controller 20A selects one of the gate lines 11 in accordance with a control signal transmitted from the timing controller 20E. The gate controller 20A applies, via the selected gate line 11, predetermined gate voltage to the TFT 14 included in the pixel 13 connected to the gate line 11.

The signal reader 20B selects one of the data lines 12 in accordance with the control signal transmitted from the timing controller 20E. The signal reader 20B reads, via the selected data line 12, a data signal according to electric charges converted by the photodiode 15 in the pixel 13. The pixel 13 relevant to the read data signal is connected to the data line 12 selected by the signal reader 20B and is connected to the gate line 11 selected by the gate controller 20A.

The timing controller 20E transmits a control signal to the voltage controller 20D in an exemplary case where the X-ray source 30 emits X-rays. The voltage controller 20D applies predetermined bias voltage to the upper electrode 46 in accordance with the control signal.

### (Operation of X-Ray Imaging Device 10)

The X-ray source 30 initially emits X-rays. The timing controller 20E transmits a control signal to the voltage controller 20D in this case. For example, a control device configured to control operation of the X-ray source 30 transmits, to the timing controller 20E, a signal indicating that the X-ray source 30 is emitting X-rays. Upon receiving the signal, the timing controller 20E transmits a control signal to the voltage controller 20D. The voltage controller 20D applies predetermined voltage (bias voltage) to the bias wire 16 in accordance with the control signal transmitted from the timing controller 20E.

The X-rays emitted from the X-ray source 30 are transmitted through the target S and enter the scintillator 10A. The X-rays having entered the scintillator 10A are converted to fluorescence (scintillation light) that enters the imaging panel 10.

When the scintillation light enters the photodiode 15 provided in each of the pixels 13 of the imaging panel 10, the photodiode 15 converts the scintillation light to electric charges according to the amount of the scintillation light.

When the TFT 14 is made in the ON state by gate voltage (positive voltage) transmitted from the gate controller 20A through the gate line 11, the signal reader 20B reads, via the data line 12, a data signal according to the electric charges converted by the photodiode 15. The image processor 20C generates an X-ray image according to the read data signal.

### (Method of Producing Imaging Panel 10)

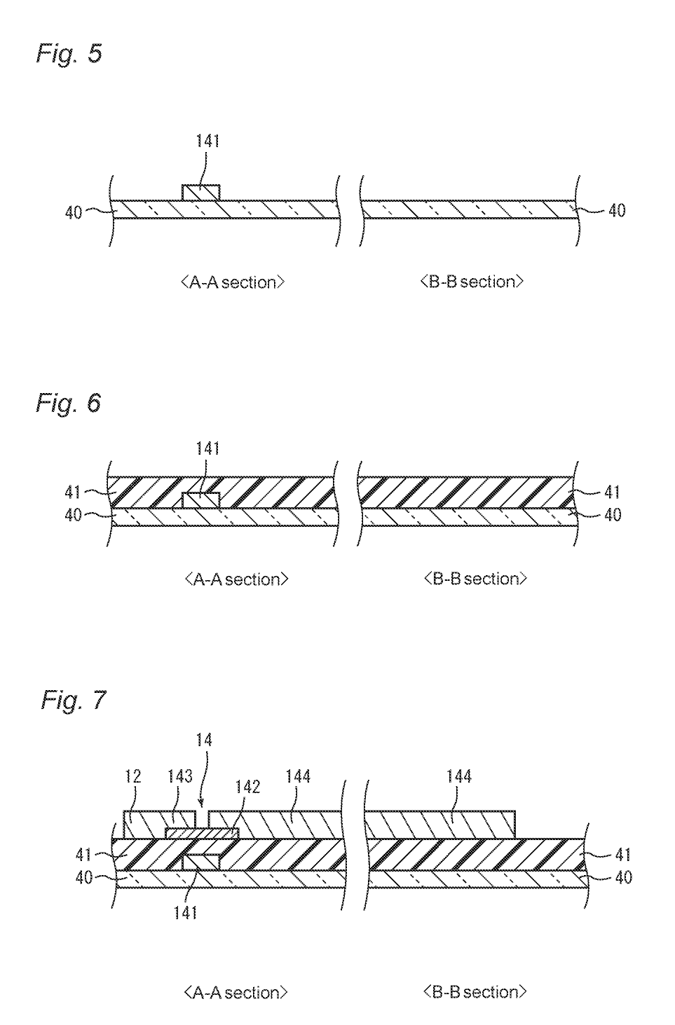

Described next is a method of producing the imaging panel 10. FIGS. 5 to 16 include sectional views taken along line A-A and sectional views taken along line B-B of the pixel 13 in respective processes of producing the imaging panel 10.

A metal film is formed on the substrate 40 by stacking aluminum and titanium through sputtering or the like. As depicted in FIG. 5, the metal film is patterned in accordance with the photolithography method to form the gate electrode 141 and the gate line 11 (see FIG. 3). The metal film is typically 300 nm thick.

As depicted in FIG. 6, the gate insulating film 41 made of a silicon oxide (SiOₓ), a silicon nitride (SiNₓ), or the like and covering the gate electrode 141 is subsequently formed on the substrate 40 in accordance with the plasma CVD method, through sputtering, or the like. The gate insulating film 41 is typically 20 to 150 nm thick.

As depicted in FIG. 7, an oxide semiconductor film is then formed on the gate insulating film 41 through sputtering or the like and is patterned in accordance with the photolithography method to form the semiconductor active layer 142. The semiconductor active layer 142 thus formed is optionally heat treated in an atmosphere containing oxygen (e.g. ambient air) at a high temperature (e.g. 350° C. or more). This reduces an oxygen defect of the semiconductor active layer 142. The semiconductor active layer 142 is typically 30 to 100 nm thick.

As depicted in FIG. 7, a metal film including titanium, aluminum, and titanium stacked in the mentioned order is subsequently formed through sputtering or the like on the gate insulating film 41 and the semiconductor active layer 142. The metal film is patterned in accordance with the photolithography method to form the source electrode 143, the data line 12, and the drain electrode 144. The source electrode 143, the data line 12, and the drain electrode 144 are typically 50 to 500 nm thick. Etching can be performed by dry etching or wet etching. Dry etching is preferred if the substrate 40 has a large area. The TFT 14 of a bottom gate type is thus formed.

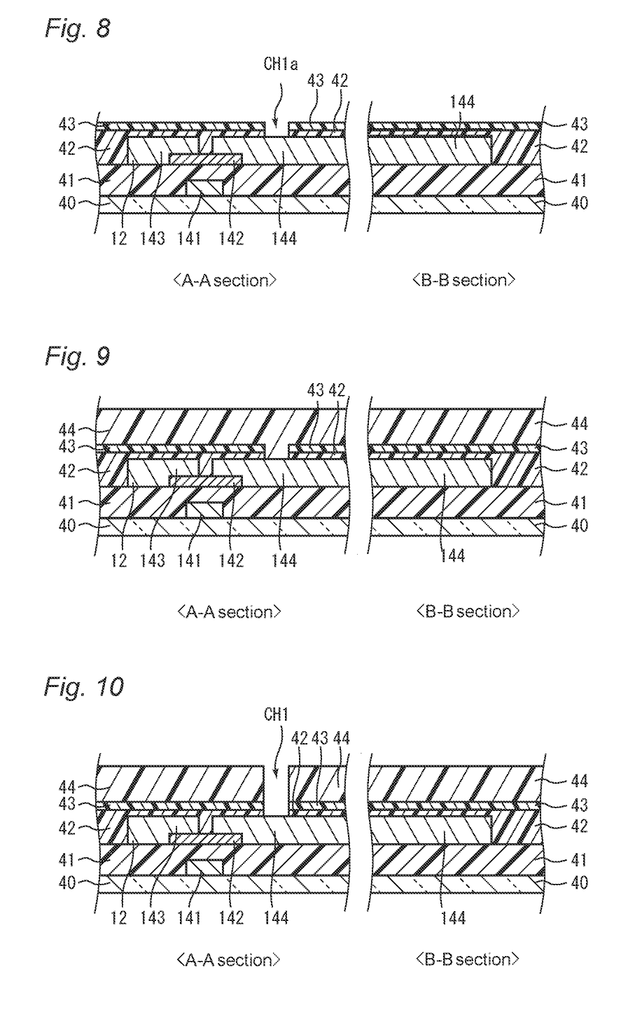

As depicted in FIG. 8, the first passivation film 42 made of silicon oxide (SiO₂) is then formed in accordance with the plasma CVD method or the like on the source electrode 143, the data line 12, and the drain electrode 144. Subsequently formed is the second passivation film 43 made of silicon nitride (SiN) and covering the first passivation film 42. Furthermore, the substrate 40 is entirely heat treated at about 350° C., and the first passivation film 42 and the second passivation film 43 are patterned in accordance with the photolithography method, to form an opening CH1a at a portion corresponding to the first contact hole CH1.

The first passivation film 42 and the second passivation film 43 can alternatively be formed in accordance with the sputtering method or the like instead of the CVD method.

As depicted in FIG. 9, the interlayer insulating film 44 (SOG film) is then formed in accordance with the slit coating method to cover the second passivation film 43. Specifically, a solution dissolving a silicon compound in an organic solvent is dripped on the second passivation film 43 in accordance with the slit coating method. Examples of the organic solvent include a mixture of methanol and glycol ether. Heat treatment at a temperature from 200 to 500° C. is subsequently performed in a nitrogen atmosphere. The organic solvent is then evaporated and polymerization reaction of the silicon compound is promoted to form the interlayer insulating film 44.

The interlayer insulating film 44 can alternatively be formed from a solution dissolving a silicon compound in an inorganic solvent. In this case, the solution dissolving the silicon compound in the inorganic solvent is dripped on the second passivation film 43 and is then heat treated at a temperature from 200 to 500° C. in a nitrogen atmosphere. The interlayer insulating film 44 is thus formed.

As depicted in FIG. 10, the interlayer insulating film 44 is subsequently patterned in accordance with the photolithography method at a portion corresponding to the opening CH1a provided in the first passivation film 42 and the second passivation film 43, to form the first contact hole CH1.

As depicted in FIG. 11, a metal film 45p made of molybdenum (Mo) is then formed on the interlayer insulating film 44 through sputtering or the like. The metal film 45p is to configure the metal layer 45 later. The metal film 45p is provided to cover also the inner wall of the first contact hole CH1. The metal film 45p is in contact with the drain electrode 144 at the first contact hole CH1.

As depicted in FIG. 11, subsequently formed on the metal film 45p through sputtering or the like are an n-type amorphous silicon layer 151p, an intrinsic amorphous silicon layer 152p, and a p-type amorphous silicon layer 153p in the mentioned order. The drain electrode 144 and the n-type amorphous silicon layer 151p are connected with each other via the metal film 45p in this state.

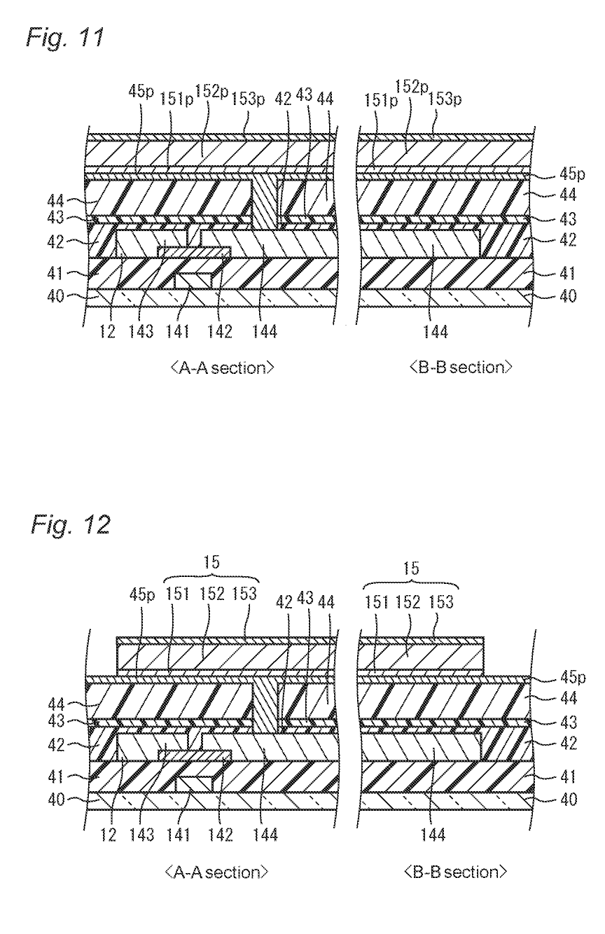

As depicted in FIG. 12, the n-type amorphous silicon layer 151p, the intrinsic amorphous silicon layer 152p, and the p-type amorphous silicon layer 153p are then patterned in accordance with the photolithography method and are dry etched to form the n-type amorphous silicon layer 151, the intrinsic amorphous silicon layer 152, and the p-type amorphous silicon layer 153. The photodiode 15 is thus obtained.

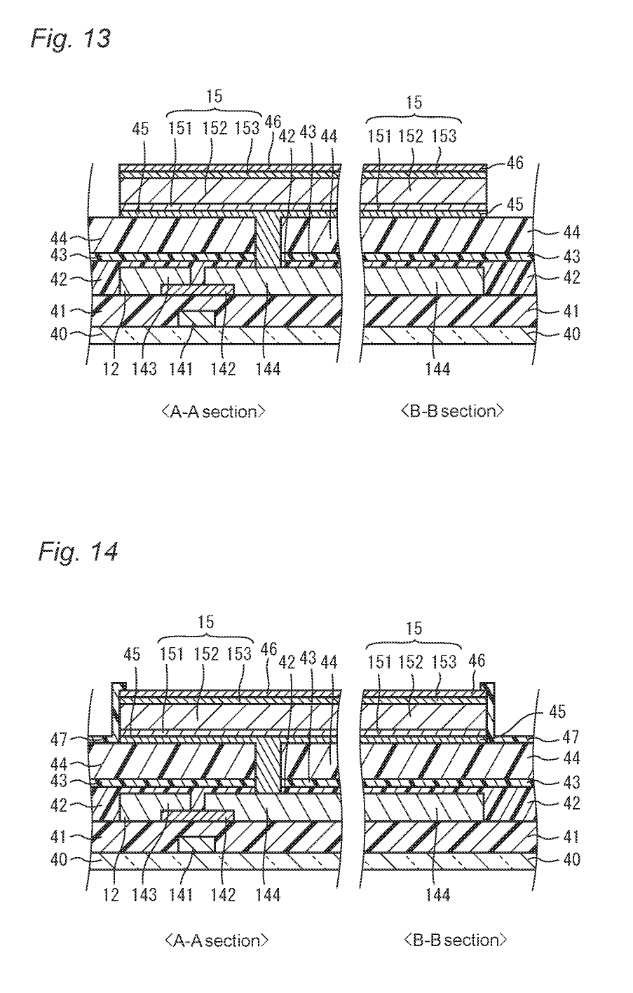

As depicted in FIG. 13, an indium zinc oxide (IZO) film is then formed on the second passivation film 43 and the photodiode 15 through sputtering or the like and is patterned in accordance with the photolithography method to form the upper electrode 46.

As depicted in FIG. 13, the metal film 45p is subsequently patterned by wet etching to form the metal layer 45.

As depicted in FIG. 14, a silicon oxide (SiO₂) film or a silicon nitride (SiN) film is then formed on the second passivation film 43 and the upper electrode 46 in accordance with the plasma CVD method or the like. The silicon oxide film or the silicon nitride film is patterned in accordance with the photolithography method to form the third passivation film 47 having an opening on the upper electrode 46 and covering only the peripheral edge of the surface of the upper electrode 46.

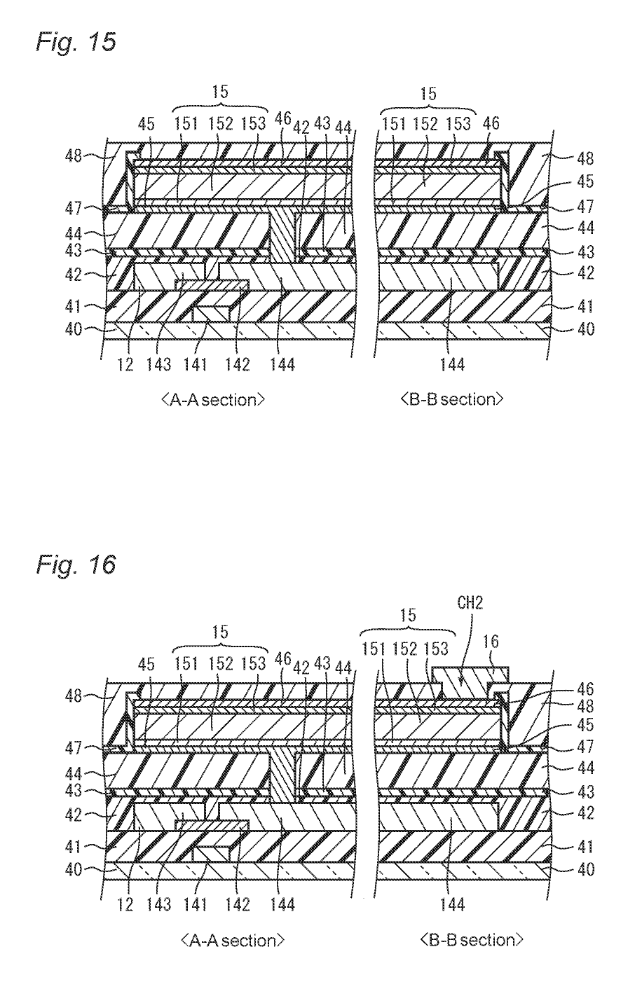

As depicted in FIG. 15, a photosensitive resin film is subsequently formed on the third passivation film 47 and is dried to form the photosensitive resin layer 48. As depicted in FIG. 16, the second contact hole CH2 reaching the upper electrode 46 is then formed in accordance with the photolithography method.

As depicted in FIG. 16, a metal film is further formed on the photosensitive resin layer 48 by stacking indium zinc oxide (IZO) and molybdenum (Mo) through sputtering or the like, and is patterned in accordance with the photolithography method, to form the bias wire 16.

In the imaging panel 10 according to the present embodiment, part of the data line 12 and part of the photodiode 15 are disposed opposite to each other in the thickness direction of the substrate to secure a large light receiving area of the photodiode 15 and achieve excellent conversion efficiency.

Furthermore, the second passivation film 43 according to the present embodiment is provided thereon with the interlayer insulating film 44 of the SOG film, to secure an adequate distance between the data line 12 and the photodiode 15 facing each other in the thickness direction of the substrate. This configuration thus reduces coupling capacitance formed between the data line 12 and the photodiode 15 and inhibits generation of signal noise at the data line 12 to suppress malfunction and operation property variation of the imaging panel 10.

Moreover, the photodiode 15 according to the present embodiment is provided therebelow with the metal layer 45 to enable forming and patterning the photodiode 15 in the state where the metal film 45p is provided entirely on the surface of the substrate. In other words, the metal film 45p covers the surface of the interlayer insulating film 44 when the photodiode 15 is patterned. The metal film 45p thus protects the interlayer insulating film 44 of the SOG film when the photodiode 15 is patterned, to prevent the SOG film from being etched together.

### Embodiment 2

Described next is an X-ray imaging device according to the embodiment 2. The X-ray imaging device according to the embodiment 2 is configured identically to that according to the embodiment 1 except that part of the imaging panel 10 is configured differently.

The imaging panel 10 is configured identically to that according to the embodiment 1 except that the interlayer insulating film 44 is not the SOG film but a photosensitive resin film.

The photosensitive resin film provided as the interlayer insulating film 44 can be made of a photosensitive resist or a nonresist of a photosensitive resin. Examples of the photosensitive resist include a novolak resist and an ArF resist. Examples of the nonresist of a photosensitive resin include polyimide and polybenzimidazole.

The imaging panel 10 is produced in accordance with a method identical to the production method according to the embodiment 1 except for the process of producing the interlayer insulating film 44. In the present embodiment, a photosensitive resin is dripped on the second passivation film 43 in accordance with the slit coating method or the like, is then patterned in accordance with the photolithography method, and is baked to obtain the interlayer insulating film 44.

The embodiment 2 provides the interlayer insulating film 44 made of the photosensitive resin between the photodiode 15 and the gate line 12, to secure a large distance between the photodiode 15 and the gate line 12 and reduce coupling capacitance formed therebetween. The embodiment 2 thus inhibits generation of signal noise at the data line 12 to suppress malfunction and operation property variation of the imaging panel 10.

### Modification Examples

Modification examples of the present invention will be described below.

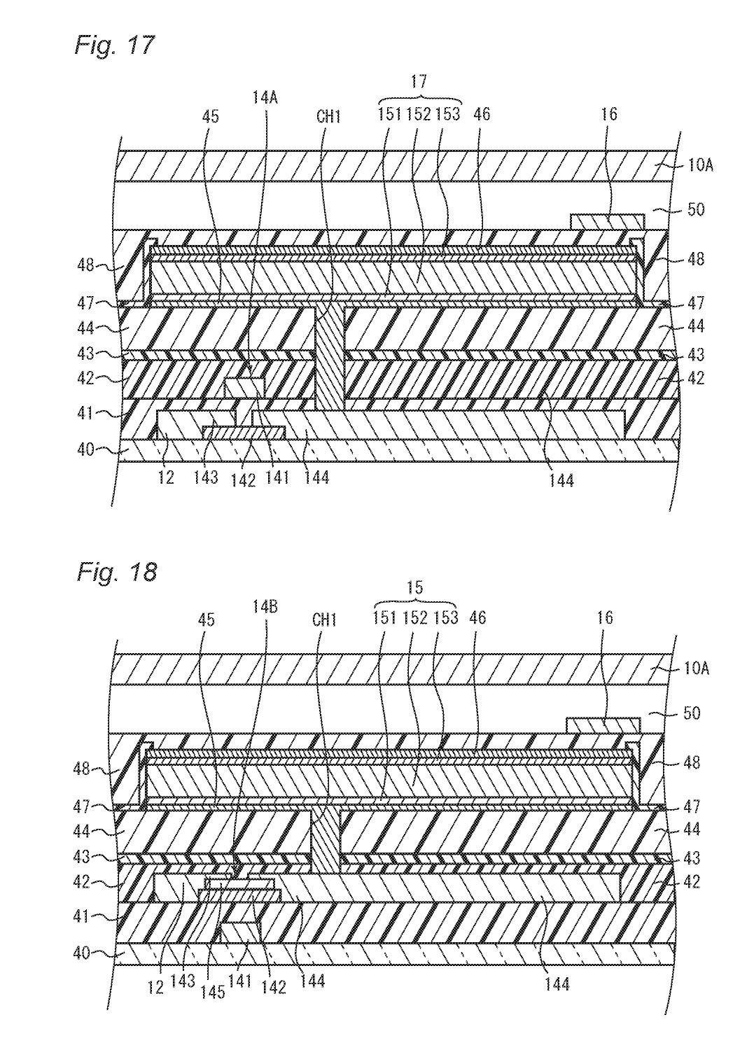

The above embodiments exemplify the imaging panel 10 including the TFTs 14 of the bottom gate type. Alternatively, the TFTs 14 can be of the top gate type as depicted in FIG. 17 or of the bottom gate type as depicted in FIG. 18.

A method of producing an imaging panel including the TFTs 14 of the top gate type of FIG. 17 will be described by referring to differences from the methods according to the above embodiments. Initially formed on the substrate 40 is the semiconductor active layer 142 made of an oxide semiconductor. The source electrode 143, the data line 12, and the drain electrode 144 are then formed by stacking titanium, aluminum, and titanium in the mentioned order on the substrate 40 and the semiconductor active layer 142.

The gate insulating film 41 made of a silicon oxide (SiOₓ), a silicon nitride (SiNₓ), or the like is subsequently formed on the semiconductor active layer 142, the source electrode 143, the data line 12, and the drain electrode 144. The gate electrode 141 and the gate line 11 are then formed by stacking aluminum and titanium on the gate insulating film 41.

After the gate electrode 141 is formed, the first passivation film 42, the second passivation film 43, and the interlayer insulating film 44 are formed on the gate insulating film 41 to cover the gate electrode 141, and the first contact hole CH1 reaching the drain electrode 144 is formed. As in the above embodiments, the metal layer 45 is to be formed on the drain electrode 144 and the photodiode 15 is to be formed on the metal layer 45.

In order to produce an imaging panel including the TFTs 14 each provided with an etch stopper layer 145 as depicted in FIG. 18, after the semiconductor active layer 142 is formed in the above embodiments, a silicon oxide (SiO₂) film is formed on the semiconductor active layer 142 in accordance with the plasma CVD method or the like. The silicon oxide (SiO₂) film is then patterned in accordance with the photolithography method to form the etch stopper layer 145. After the etch stopper layer 145 is formed, the source electrode 143, the data line 12, and the drain electrode 144 are to be formed by stacking titanium, aluminum, and titanium in the mentioned order on the semiconductor active layer 142 and the etch stopper layer 145.

The above embodiments provide the indirect X-ray imaging device 1 including the scintillator 10A. The present invention is not particularly limited thereto. The present invention is applicable also to a direct X-ray imaging device including no scintillator. Specifically, an imaging panel included in the direct X-ray imaging device includes a photoelectric transducer configured to convert X-rays received from the X-ray source 30 to electricity.

The embodiments of the present invention described above merely exemplify to achieve the present invention. The present invention should not be limited to the above embodiments, and can be achieved with appropriate modifications to the above embodiments without departing from the spirit of the present invention.

### INDUSTRIAL APPLICABILITY

The present invention is applicable to an imaging panel, a method of producing the imaging panel, and an X-ray imaging device.

1. An imaging panel configured to generate an image in accordance with X-rays having been transmitted through a target, the imaging panel comprising:
a substrate;
a plurality of thin film transistors provided on the substrate;
a data line configured to supply the plurality of thin film transistors with a data signal;
an interlayer insulating film provided on the substrate and covering the thin film transistors and the data line;
a plurality of contact holes penetrating the interlayer insulating film and reaching the thin film transistors, respectively;
a plurality of metal layers each covering an inner side surface of a corresponding one of the contact holes and the interlayer insulating film and connected to a corresponding one of the thin film transistors; and
a plurality of photodiodes each provided on and in contact with a corresponding one of the metal layers; wherein
part of the data line and part of the photodiode are disposed opposite to each other in a thickness direction of the substrate, and
the interlayer insulating film is an SOG film or a photosensitive resin film.

2. The imaging panel according to claim 1, wherein
a thickness of the interlayer insulating film is in a range of 1 to 5 μm.

3. The imaging panel according to claim 1, further comprising:
a first insulating film covering the thin film transistor and the data line and provided below the interlayer insulating film; wherein
the interlayer insulating film has a dielectric constant less than that of the first insulating film.

4. The imaging panel according to claim 1, wherein
the interlayer insulating film has a relative dielectric constant in a range of 2.5 to 4.

5. An X-ray imaging device comprising:
the imaging panel according to claim 1;
a controller configured to control gate voltage of each of the thin film transistors and read a data signal according to electric charges converted by the photodiodes via the data line; and
an X-ray source configured to emit X-rays.

6. A method of producing an imaging panel configured to generate an image in accordance with X-rays having been transmitted through a target, the method comprising:
forming a plurality of thin film transistors and a data line on a substrate;
forming, on the substrate, an interlayer insulating film covering the thin film transistors and the data line in accordance with a spin coating method or a slit coating method;
forming, in the interlayer insulating film, a plurality of contact holes each reaching a corresponding one of the thin film transistors;
forming a metal film covering the interlayer insulating film and an inner side surface of each of the contact holes; and
forming a plurality of photodiodes respectively corresponding to the contact holes by forming a semiconductor film and then patterning the semiconductor film into island shapes by dry etching.

7. The method of producing the imaging panel according to claim 6, the method further comprising:
obtaining a metal layer, after forming the plurality of photodiodes, by wet etching to remove a region not covered with the photodiodes in the metal film.
